(19) United States
(12) Patent Application Publication
(10) Pub. No.: US 2025/0112189 A1
(43) Pub. Date: Apr. 3, 2025

(54) Die and Wafer Level Processing of Laser Diodes and Other Semiconductor Devices on Non-Native Semiconductor Wafers

(71) Applicant: Apple Inc., Cupertino, CA (US)

(72) Inventors: Nicolas Hotellier, Chmpagnier (FR); Christophe Verove, Tokyo (JP); Amaud Laflaquiere, Paris (FR); David Coulon, Aix-en-provence (FR); Siddharth Joshi, Saint-Egreve (FR); Stephane Zoll, Saint-Ismier (FR); Keith Lyon, San Jose, CA (US); Cristiano L. Niclass, San Jose, CA (US)

(21) Appl. No.: 18/673,101

(22) Filed: May 23, 2024

Related U.S. Application Data
(60) Provisional application No. 63/541,612, filed on Sep. 29, 2023.

(51) Int. Cl. H01L 23/00; H01L 27/146; H01S 5/183

(52) U.S. Cl. CPC H01L 24/08; H01S 5/18344; H10F 39/8063; H10F 39/809; H01L 2224/08145

(57) ABSTRACT

An electronic device includes a set of semiconductor layers defining a set of semiconductor mesas. A first dielectric abuts the set of semiconductor layers at a perimeter of the set of semiconductor layers. A second dielectric is disposed on the set of semiconductor mesas. A set of conductors is routed in or on the second dielectric. The set of conductors is electrically connected to at least one active device defined in at least one semiconductor mesa of the set of semiconductor mesas. The set of conductors is configured to route electrical signals to or from the at least one semiconductor mesa, and the set of conductors includes a set of hybrid bonding pads on the second dielectric.

### CROSS-REFERENCE TO RELATED APPLICATION

This application is a nonprovisional and claims the benefit under 35 U.S.C. § 1.119(e) of U.S. Provisional Patent Application No. 63/541,612, filed Sep. 29, 2023, the contents of which are incorporated herein by reference as if fully disclosed herein.

### FIELD

The described embodiments generally relate to semiconductor devices and, in some embodiments, to laser diodes (e.g., vertical cavity surface-emitting laser (VCSEL) diodes), photodiodes (e.g., resonant cavity photodiodes), single-photon avalanche diodes (SPADs), and other types of semiconductor-based electromagnetic radiation (e.g., visible or non-visible light) emitters and detectors.

### BACKGROUND

Nearly all of today's devices include some form of semiconductor device. Just a few examples of devices that may include semiconductor devices are handheld devices (e.g., smartphones, other types of communication devices, navigation devices, styluses, and electronic pencils), wearable devices (e.g., wrist-worn devices such as watches and fitness tracking devices, and head-mounted devices such as headsets, glasses, and earbuds), computers (e.g., tablet computers and laptop computers), vehicles, and robots.

Semiconductor devices such as electromagnetic radiation emitters and detectors may include an array of elements, such as an array of VCSEL diodes (hereinafter just referred to as VCSELs) or an array of SPADs. The area or mass of such an array can be reduced by reducing the pitch of the elements that are included in the array. In addition to the benefits of reducing the area or mass of such an array within a handheld, wearable, or other type of portable device, reducing the pitch of an array's elements can provide an increase in resolution (e.g., for a structured light projector, such as an infrared dot projector, or for a light detector, such as a two-dimensional (2D) or three-dimensional (3D) image sensor (e.g., a light detection and ranging (LIDAR) system)). Reducing the area or mass of an array of elements can also decrease the power consumption of the array (e.g., for the above-described emitters and detectors, and in particular for a device such as a flood illumination source).

### SUMMARY

Embodiments of the systems, devices, methods, and apparatus described in the present disclosure employ, or benefit from, die and wafer level processing of laser diodes and other semiconductor devices on non-native semiconductor wafers.

In a first aspect, the present disclosure describes an electronic device. The electronic device may include a set of semiconductor layers defining a set of semiconductor mesas. A first dielectric may abut the set of semiconductor layers at a perimeter of the set of semiconductor layers. A second dielectric may be disposed on the set of semiconductor mesas. A set of conductors may be routed in or on the second dielectric. The set of conductors may be electrically connected to at least one active device defined in at least one semiconductor mesa of the set of semiconductor mesas. The set of conductors may be configured to route electrical signals to or from the at least one semiconductor mesa. The set of conductors may include a set of hybrid bonding pads on the second dielectric.

In a second aspect, the present disclosure describes another electronic device. The electronic device may include a first set of semiconductor layers defining a set of semiconductor mesas. A dielectric may be disposed on the set of semiconductor mesas. A set of conductors may be routed in the dielectric. The set of conductors may include a set of conductive vias electrically connected to at least one active device defined in at least one semiconductor mesa of the set of semiconductor mesas. The set of conductors may be configured to route electrical signals to or from the at least one semiconductor mesa.

In a third aspect, the present disclosure describes another electronic device. The electronic device may include a set of semiconductor layers defining a set of semiconductor mesas. A first dielectric may be disposed on the set of semiconductor mesas. A first set of conductors may be routed in or on the first dielectric. The first set of conductors may be electrically connected to at least one active device defined in at least one semiconductor mesa of the set of semiconductor mesas. The first set of conductors may be configured to route electrical signals to or from the at least one semiconductor mesa. The first set of conductors may include a first set of hybrid bonding pads on the first dielectric. A second dielectric may be disposed on the first dielectric. A second set of conductors may be routed in or on the second dielectric. The second set of conductors may include a second set of hybrid bonding pads bonded to the first set of hybrid bonding pads.

In addition to the exemplary aspects and embodiments described above, further aspects and embodiments will become apparent by reference to the drawings and by study of the following description.

### BRIEF DESCRIPTION OF THE DRAWINGS

The disclosure will be readily understood by the following detailed description in conjunction with the accompanying drawings, wherein like reference numerals designate like structural elements, and in which:

FIGS. 1A and 1B show an example electronic device having a die embedded in one or more dielectrics on a silicon backplane or interposer;

FIG. 2 shows a first variation of the electronic device described with reference to FIGS. 1A and 1B;

FIG. 3 shows a second variation of the electronic device described with reference to FIGS. 1A and 1B;

FIGS. 4A-4G illustrate an example method of making the electronic device shown in FIGS. 1A and 1B, 2, or 3;

FIGS. 5A and 5B show an example electronic device having a first die and a second die embedded in one or more dielectrics on a silicon backplane or interposer;

FIG. 6 shows a variation of the electronic device described with reference to FIGS. 5A and 5B; and

FIGS. 7A-7D, in combination with FIGS. 4A-4D, illustrate an example method of making the electronic device shown in FIGS. 5A and 5B, or 6.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following description is not intended to limit the embodiments to one preferred embodiment. To the contrary, it is intended to cover alternatives, modifications, and equivalents as can be included within the spirit and scope of the described embodiments as defined by the appended claims.

Semiconductor devices may be fabricated and processed on different size semiconductor wafers. For example, 4″, 6″, 8″, 10″, and 12″ diameter semiconductor wafers are currently available. Over time, the diameter of the largest semiconductor wafer that can be fabricated and processed has grown. So too have the capabilities of the processing toolsets that are available for larger diameter semiconductor wafers grown and advanced.

At times, a semiconductor fabrication and processing facility may only be able to fabricate and process semiconductor devices on a particular diameter of semiconductor wafer. At times, it may be customary to fabricate and process a particular type of semiconductor device on a semiconductor wafer of a particular diameter. For example, VCSELs are typically fabricated and processed on 4″ or 6″ diameter semiconductor wafers. However, the processing toolsets available for 4″ and 6″ diameter semiconductor wafers are less advanced than the processing toolsets available for larger diameter semiconductor wafers.

Described herein are die and wafer level processing techniques for laser diodes and other semiconductor devices, and electronic devices that may result from the use of such techniques. In accordance with the described techniques, a set of semiconductor layers may be formed on a first semiconductor wafer. The first semiconductor wafer may then be divided into a plurality of die (or coupons), some or all of which may be bonded to a second semiconductor wafer and then processed to form one or more semiconductor devices (e.g., VCSELs, SPADs, or other semiconductor devices). The second semiconductor wafer may have a larger diameter than the first semiconductor wafer, which may enable the die diced from the first semiconductor wafer to be processed with a different (and usually more advanced) processing toolset (e.g., the processing toolset for a 12″ diameter semiconductor wafer may provide access to copper (Cu) damascene processing and hybrid bonding). In alternative embodiments, the second semiconductor wafer may have a smaller diameter than the first semiconductor wafer, or the semiconductor devices may be partially processed on the first semiconductor wafer and then further processed on the second semiconductor wafer, or the first and second semiconductor wafers may have a same diameter but include different materials.

In some embodiments, the semiconductor devices may be formed with a finer pitch on the second semiconductor wafer than if they were formed on the first semiconductor wafer. For example, the pitch of VCSELs on a 4″ or 6″ diameter semiconductor wafer is currently limited to about 16 microns, with contact sizes limited to about 10 microns, whereas the pitch of VCSELs formed as described herein, on a 12″ diameter semiconductor wafer, may be on the order of 5-10 microns.

Fabricating and processing semiconductor devices as described herein may also enable different types of semiconductor devices, including different semiconductor substrates or semiconductor layers, to be combined and/or processed on a common semiconductor substrate. For example, VCSELs and SPADs may be combined. This may allow the different types of semiconductor wafers to be combined in a single, advanced die, and in some cases share circuitry or other components.

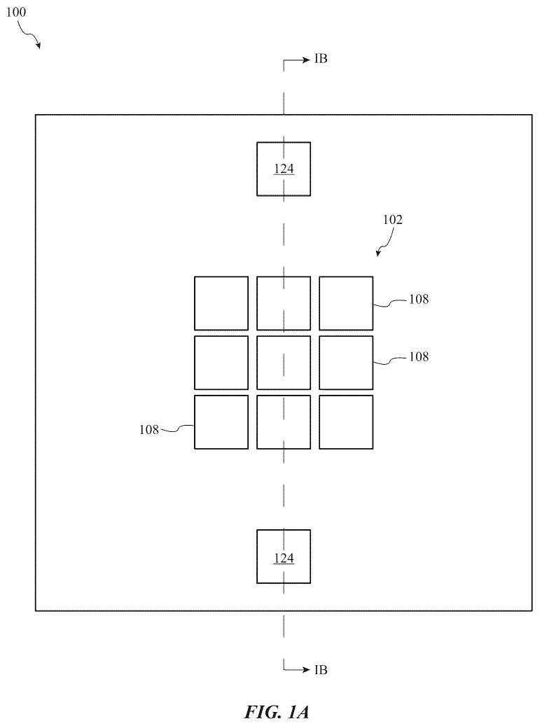

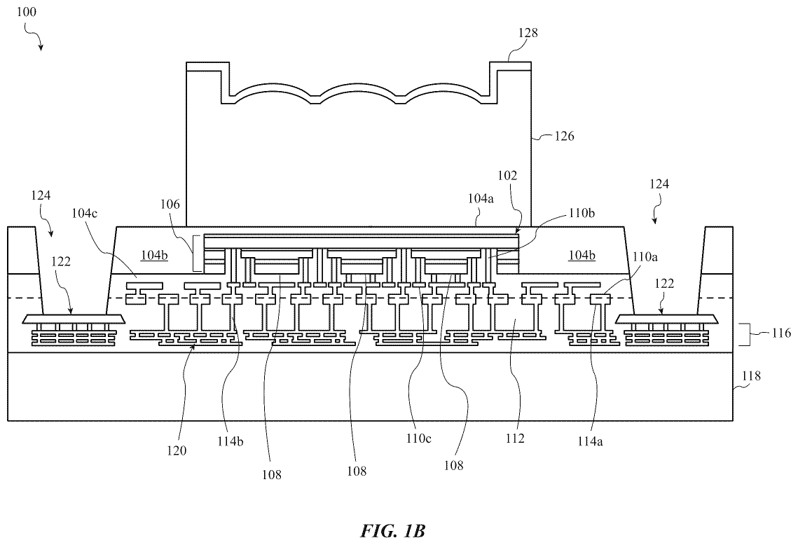

These and other systems, devices, methods, and apparatus are described with reference to FIGS. 1-7D. However, those skilled in the art will readily appreciate that the detailed description given herein with respect to these figures is for explanatory purposes only and should not be construed as limiting.

Directional terminology, such as “top”, “bottom”, “upper”, “lower”, “front”, “back”, “over”, “under”, “above”, “below”, “left”, “right”, etc. is used with reference to the orientation of some of the components in some of the figures described below. Because components in various embodiments can be positioned in a number of different orientations, directional terminology is used for purposes of illustration and is not always limiting. The directional terminology is intended to be construed broadly, and therefore should not be interpreted to preclude components being oriented in different ways. Also, as used herein, the phrase “at least one of” preceding a series of items, with the term “and” or “or” to separate any of the items, modifies the list as a whole, rather than each member of the list. The phrase “at least one of” does not require selection of at least one of each item listed; rather, the phrase allows a meaning that includes at a minimum one of any of the items, and/or at a minimum one of any combination of the items, and/or at a minimum one of each of the items. By way of example, the phrases “at least one of A, B, and C” or “at least one of A, B, or C” each refer to only A, only B, or only C; any combination of A, B, and C; and/or one or more of each of A, B, and C. Similarly, it may be appreciated that an order of elements presented for a conjunctive or disjunctive list provided herein should not be construed as limiting the disclosure to only that order provided.

FIGS. 1A and 1B show an example electronic device 100 having a die 102 embedded in one or more dielectrics 104 on a silicon (Si) backplane or interposer. FIG. 1A shows a plan view of the electronic device 100. FIG. 1B shows a cross-sectional elevation of the electronic device 100, taken along line IB-IB in FIG. 1A.

The die 102 may include a first set of semiconductor layers 106. In some embodiments, the first set of semiconductor layers 106 may define a set of semiconductor mesas 108 (i.e., stacks of semiconductor layers extending from one or more base semiconductor layers). In FIG. 1, the set of semiconductor mesas 108 is shown inverted, with the semiconductor mesas extending toward the bottom of the electronic device 100). In some embodiments, the set of semiconductor mesas 108 may be formed in a common set of semiconductor layers (e.g., by forming the common set of semiconductor layers, and then etching trenches in the common set of semiconductor layers to define the set of semiconductor mesas 108). In some embodiments, the first set of semiconductor layers 106 may include III-V semiconductor materials.

In some embodiments, the set of semiconductor mesas 108 may define at least one active device. For example, the set of semiconductor mesas 108 may define at least one laser diode, such as at least one surface-emitting laser diode (e.g., at least one VCSEL diode or at least one horizontal cavity surface-emitting laser (HCSEL) diode). In some embodiments, the set of semiconductor mesas 108 may define at least one photodetector, such as at least one resonant cavity photodiode (RCPD). In some embodiments, a single semiconductor mesa of the set of semiconductor mesas 108 may define both a VCSEL and an RCPD (e.g., an RCPD integrated with a VCSEL). Alternatively, the semiconductor mesas 108, or other structures formed in the first set of semiconductor layers 106, may define light-emitting diodes (LEDs), edge-emitting laser (EEL) diodes, or other types of semiconductor devices.

A first dielectric 104a may be disposed on the set of semiconductor mesas 108 on a first side of the set of semiconductor mesas 108. The first dielectric 104a may abut a primary light emission surface of the set of semiconductor mesas 108. A second dielectric 104b may abut the first set of semiconductor layers 106 at a perimeter of the first set of semiconductor layers 106. In some embodiments the second dielectric 104b may surround the perimeter of the set of semiconductor layers 106 (as shown). A third dielectric 104c may also be disposed on the set of semiconductor mesas 108 but may be disposed on a second side of the set of semiconductor mesas 108, opposite the first side of the set of semiconductor mesas 108. The third dielectric 104c may abut the top of each semiconductor mesa in the set of semiconductor mesas 108 and extend between adjacent semiconductor mesas in the set of semiconductor mesas 108.

Each of the first, second, and third dielectrics 104a, 104b, 104c may be formed of the same or different materials and may include one or more layers or depositions of dielectric. In some embodiments, each of the first, second, and third dielectrics 104a, 104b, 104c may include one or more layers of silicon dioxide (SiO₂), silicon nitride (SiN), or a combination thereof.

A first set of conductors 110 may be routed in or on the third dielectric 104c. The first set of conductors 110 may electrically connect to at least one active device defined in at least one semiconductor mesa of the set of semiconductor mesas 108. The first set of conductors 110 may be configured to route electrical signals to or from the at least one semiconductor mesa. The first set of conductors 110 may include a first set of hybrid bonding pads 110a on the third dielectric 104c. The first set of conductors 110 may also include a set of conductive vias 110b that is electrically connected to at least one active device defined in the set of semiconductor mesas 108 (e.g., to both an anode and cathode of each active device of the at least one active device). The first set of conductors 110 may also include one or more conductive traces 110c that route electrical signals within a layer (i.e., a redistribution layer). In some embodiments, the first set of conductors 110 may electrically connect the set of semiconductor mesas 108 to one or more transistors or other electrical components formed in or on the third dielectric 104c.

A fourth dielectric 112 may be disposed on the third dielectric 104c. A second set of conductors 114 may be routed in or on the fourth dielectric 112. The second set of conductors 114 may include a second set of hybrid bonding pads 114a. The second set of hybrid bonding pads 114a may be bonded to the first set of hybrid bonding pads 110a at a wafer-to-wafer (W2W) bonding interface.

The fourth dielectric 112, in addition to a second set of semiconductor layers and a set of metal routing layers (collectively referred to as a set of semiconductor and metal layers 116), may be initially formed on a semiconductor substrate 118, with the set of semiconductor and metal layers 116 disposed between the semiconductor substrate 118 and the second set of hybrid bonding pads 114a, prior to bonding the second set of hybrid bonding pads 114a to the first set of hybrid bonding pads 110a. The set of semiconductor and metal layers 116 may include the same and/or different materials than the first set of semiconductor layers 106. In some embodiments, the semiconductor substrate 118 may be a silicon substrate. In some embodiments, part or all of the semiconductor substrate 118 may be removed after the second set of hybrid bonding pads 114a is bonded to the first set of hybrid bonding pads 110a.

In some embodiments, a set of semiconductor structures 120 (e.g., transistors or other components) may be formed (or included) in the set of semiconductor and metal layers 116. Conductors 114b (e.g., conductive vias and/or conductive traces) in the second set of conductors 114 may electrically couple semiconductor structures in the set of semiconductor structures 120 to the second set of hybrid bonding pads 114a. By means of bonding the second set of hybrid bonding pads 114a to the first set of hybrid bonding pads 110a, at least one semiconductor structure in the set of semiconductor structures 120 may be electrically coupled to the at least one active device in the set of semiconductor mesas 108.

In some embodiments, conductors in the second set of conductors 114 may electrically couple semiconductor structures in the set of semiconductor structures 120 and/or conductors in the first set of conductors 110 to one or more surface electrical contacts (e.g., conductive pads) 122 disposed in one or more wells 124 etched through the set of dielectrics 104, fourth dielectric 112, and some or all of the semiconductor layers in the set of semiconductor and metal layers 116.

Optionally, a dielectric optical element 126 may be attached to the first set of semiconductor layers 106, on the first side of the set of semiconductor mesas 108. The dielectric optical element 126 may define at least one lens positioned to direct light to or from the at least one active device in the set of semiconductor mesas 108. In some embodiments, the dielectric optical element 126 may include a glass, a plastic, or a crystal (e.g., a sapphire). In some embodiments, one or more coatings or surface treatments 128 may be deposited on or applied to the dielectric optical element 126, to reflect a portion of light emitted by an active device (e.g., a laser diode) back toward the laser diode and function as an extent of an extended laser cavity. The extended laser cavity, in combination with a VCSEL, may form a VECSEL.

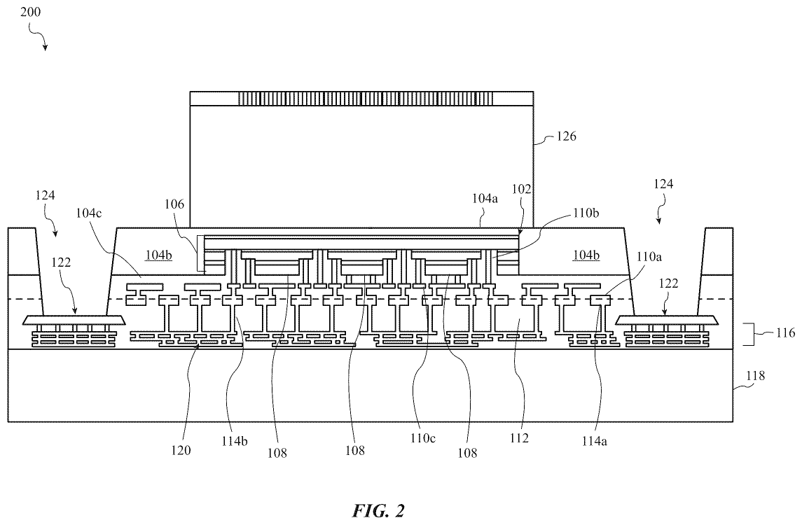

FIG. 2 shows a first variation 200 of the electronic device described with reference to FIGS. 1A and 1B. In the first variation 200, the dielectric optical element 126 is a multivariate optical element (MOE) instead of (or in addition to) one or more lenses.

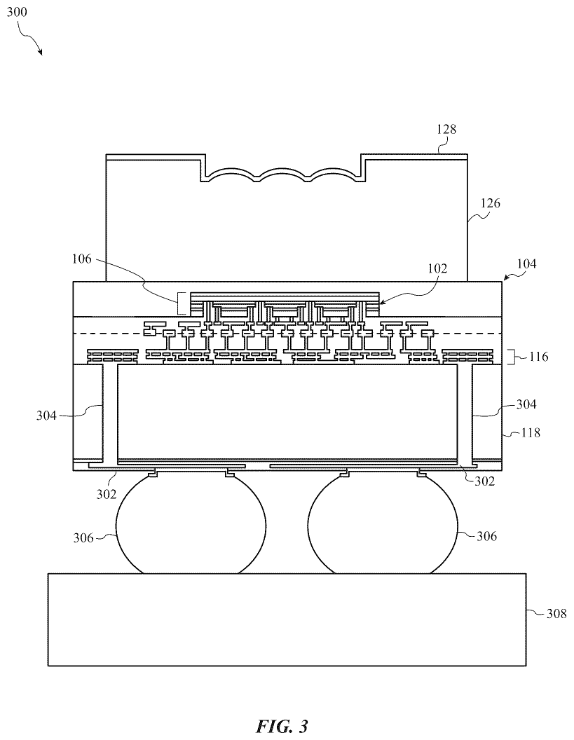

FIG. 3 shows a second variation 300 of the electronic device described with reference to FIGS. 1A and 1B. In the second variation 300, there are no surface electrical contacts 122 disposed in a well 124. Instead, electrical contacts (e.g., conductive pads) 302 are formed on a side of the semiconductor substrate 118 opposite a side of the semiconductor substrate 118 on which the set of semiconductor and metal layers 116 is formed. Conductive vias 304 formed through the semiconductor substrate 118 may electrically couple the electrical contacts 302 to conductors in the second set of conductors 114, and thereby to semiconductor structures in the set of semiconductor structures 120 and/or conductors in the first set of conductors 110. Optionally, solder balls 306 or other conductive features may be electrically coupled to the electrical contacts 302 to route electrical signals to or from the at least one active device in the set of semiconductor mesas 108; to or from at least one semiconductor structure in the set of semiconductor structures 120; or to other elements, grounds, etc. By way of example, the solder balls 306 are shown to be electrically coupled to a printed circuit board (PCB) 308.

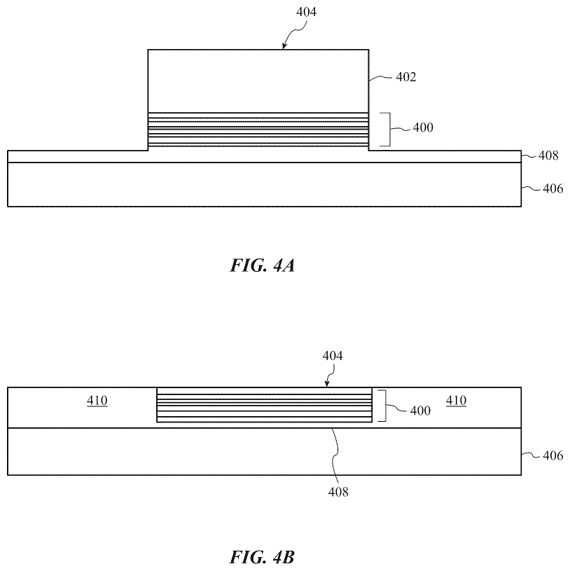

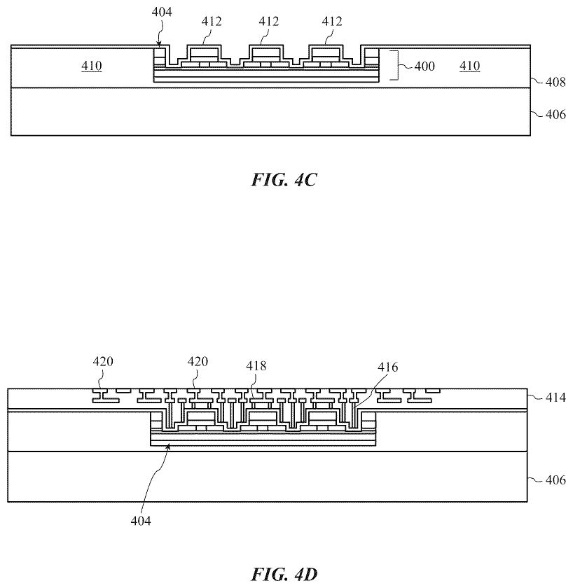

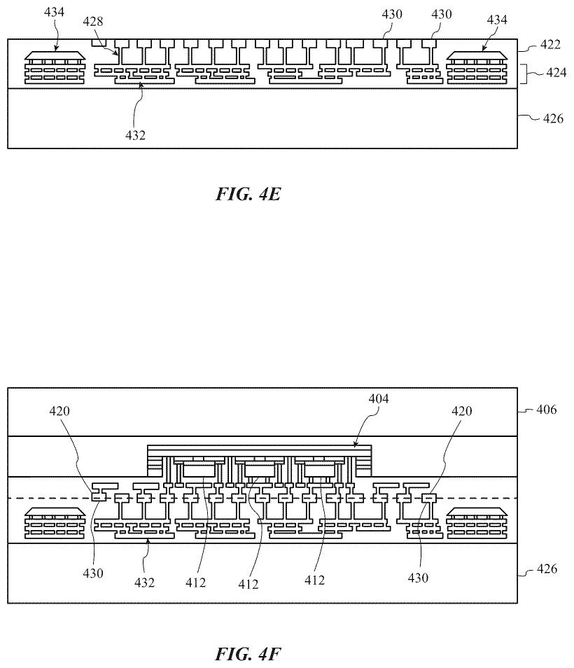

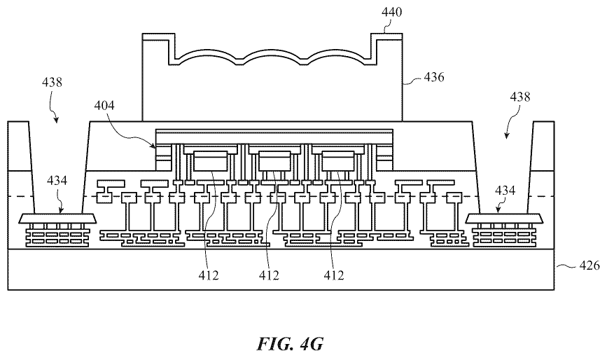

FIGS. 4A-4G illustrate an example method of making the electronic device shown in any of FIGS. 1A and 1B, 2, or 3.

The method may include forming a first set of semiconductor layers 400 on a first semiconductor substrate 402. In some embodiments, the first semiconductor substrate 402 may be a semiconductor wafer, such as 4″, 6″, or 8″ diameter semiconductor wafer. In some embodiments, the semiconductor substrate 402 and first set of semiconductor layers 400 may include a set of III-V semiconductor materials. In some embodiments, the semiconductor substrate 402 may be a germanium (Ge) or other type of semiconductor wafer on which one or more layers of indium phosphide (InP), gallium arsenide (GaAs), gallium nitride (GaN), indium antimony (InSb) or other materials are epitaxially grown. Optionally, one or more anti-reflective coatings (ARCs) may be deposited on the first set of semiconductor layers 400. In some embodiments, the first set of semiconductor layers 400 may be epitaxially grown on a semiconductor wafer and then the semiconductor wafer may be diced into several die (or coupons). Optionally, the die may be thinned (e.g., by removing part or all of the semiconductor substrate 402). One such die 404 (or coupon) is shown in FIG. 4A. At this stage of the method, no particular active device has been formed in the first set of semiconductor layers 400.

The die 404 may be bonded to a carrier wafer 406 (e.g., a Si wafer) with the first set of semiconductor layers 400 disposed between the first semiconductor substrate 402 and the carrier wafer 406. The die 404 may be bonded using any currently known or otherwise discovered die-to-wafer (D2W) bonding process. Optionally, a first dielectric 408 (e.g., SiO₂ or SiN) may be formed on the carrier wafer 406 before the die 404 is bonded to the carrier wafer 406. A dielectric may optionally be formed on the die 404 (and in some cases, this may be done before the die 404 is diced from its semiconductor wafer. In some cases, the first dielectric 408 and/or dielectric on the die 404 may assist in the D2W bonding. Although only one die 404 is shown in FIG. 4A, several die may be bonded to the carrier wafer 406, for subsequent processing in parallel.

In some embodiments, the carrier wafer 406 may be a larger diameter semiconductor wafer than the semiconductor wafer on which the die 404 was formed. For example, the carrier wafer 406 may be a 12″ diameter semiconductor wafer. An advantage of dicing die from a smaller semiconductor wafer and bonding them to a larger semiconductor wafer is that the processing toolset available for the larger semiconductor wafer may be more advanced than the processing toolset available for the smaller semiconductor wafer. If the opposite were true, the method could be performed by bonding die diced from a larger semiconductor wafer on a smaller semiconductor wafer.

After bonding the die 404 to the carrier wafer 406, any remaining portion of the semiconductor substrate 402 may be removed, as shown in FIG. 4B. After removing the semiconductor substrate 402, a second dielectric 410 (e.g., SiO₂ or SiN) may be formed or deposited to abut the first set of semiconductor layers 400 at a perimeter of the first set of semiconductor layers 400. When multiple die are bonded to the carrier wafer 406, the second dielectric 410 may fill the areas between the die. A chemical mechanical planarization (CMP) process may then be performed to planarize the second dielectric 410 and first set of semiconductor layers 400. Alternatively, the second dielectric 410 may be formed on the carrier wafer 406 before the die 404 is bonded to the carrier wafer 406; a cavity may be etched in the second dielectric 410; the die 404 may be bonded to the carrier wafer 406 within the cavity; additional dielectric may optionally be formed to fill any gaps between the walls of the cavity and the die 404; and a CMP process may be performed.

As shown in FIG. 4C, a set of semiconductor mesas 412 may be etched in the first set of semiconductor layers 400. By way of example, three semiconductor mesas are shown, but given the depth of the die 404 (not shown), additional semiconductor mesas may be etched. In some embodiments, more or fewer semiconductor mesas (and even just one) may be etched, depending on the area of the die 404 and the area of each semiconductor mesa. In some embodiments, the set of semiconductor mesas 412 may have a pitch (e.g., center-to-center spacing) between 5 and 10 micrometers (μm), which is currently not possible (i.e., not an achievable pitch) with a processing toolset for a 4″, 6″, or 8″ diameter semiconductor wafer. After etching the set of semiconductor mesas 412, oxidation, passivation, and/or other processes may be performed on the set of semiconductor mesas 412.

In some embodiments, the first set of semiconductor layers 400 may include an active layer (e.g., a layer of quantum wells). In some embodiments, the first set of semiconductor layers 400 may include two or more active layers. A single active layer may enable each semiconductor mesa in the set of semiconductor mesas 412 to be operated as a laser diode, such as a surface-emitting laser diode (e.g., a VCSEL diode or a HCSEL diode), or as a photodetector, such as an RCPD. Multiple active layers may enable a single semiconductor mesa to define both a VCSEL and an RCPD; a VCSEL and two RCPDs; or other stack-ups, depending on the number of active layers and the desired operation.

In some embodiments, the set of semiconductor mesas 412 need not be formed and the first set of semiconductor layers 400 may be processed in other ways, for other purposes, using the processing toolset available for the carrier wafer 406.

As shown in FIG. 4D, a third dielectric 414 (e.g., SiO₂ or SiN) may be formed on the set of semiconductor mesas 412 and may fill the gaps between semiconductor mesas as well as provide one or more dielectric layers on top of the semiconductor mesas. Another CMP process may be performed. A first set of conductors including a set of conductive vias 416 may be formed in the third dielectric 414 to provide electrical connections to various semiconductor layers of the set of semiconductor mesas 412. Of note, conductive vias 416 such as those shown may be formed using a processing toolset for a 12″ diameter semiconductor wafer, but not a processing toolset of a 4″, 6″, or 8″ diameter semiconductor wafer. In some embodiments, the first set of conductors may also include a set of conductive traces 418, embedded in the third dielectric 414 and used to route electrical signals to or from the set of semiconductor mesas 412 (i.e., in one or more redistribution layers). The conductive vias 416, conductive traces 418, and/or other conductive vias (i.e., the first set of conductors) may electrically connect at least one active device in the set of semiconductor mesas to a first set of hybrid bonding pads 420 (which first set of hybrid bonding pads 420 may also be considered part of the first set of conductors).

In parallel with the above operations, a fourth dielectric 422 (e.g., SiO₂ or SiN) and optional second set of semiconductor layers and set of metal routing layers (collectively referred to as a set of semiconductor and metal layers 424) may be formed on a semiconductor substrate 426 (e.g., another Si wafer). See, FIG. 4E. A second set of conductors 428 may be routed in or on the fourth dielectric 422 and may include a second set of hybrid bonding pads 430.

The set of semiconductor and metal layers 424 may be disposed between the semiconductor substrate 426 and the second set of hybrid bonding pads 430. In some embodiments, the set of semiconductor and metal layers 424 may include a set of semiconductor structures 432 (e.g., transistors or other components). The set of semiconductor structures 432 may define, for example, one or more laser diode driver (LDD) circuits that may be electrically coupled to the at least one active device (in the set of semiconductor mesas 412) via the second set of conductors 428 and the first set of conductors (e.g., the conductive vias 416, the conductive traces, and the first set of hybrid bonding pads 420). If the at least one active device includes a photodetector (e.g., an RCPD), the set of semiconductor structures 432 may also define a sense circuit or readout circuit.

Conductors (e.g., conductive vias and/or conductive traces) in the second set of conductors 428 may electrically couple semiconductor structures in the set of semiconductor structures 432 to the second set of hybrid bonding pads 430.

In some embodiments, conductors in the second set of conductors 428 may electrically couple semiconductor structures in the set of semiconductor structures 432 and/or conductors in the first set of conductors to one or more electrical contacts 434 (e.g., conductive pads).

As shown in FIG. 4F, the second set of hybrid bonding pads 430 may be bonded to the first set of hybrid bonding pads 420 in a wafer-to-wafer (W2W) bonding process. The W2W bonding process may be any currently known or otherwise discovered W2W bonding process. In some embodiments, the W2W bonding process may involve a bonding of same size semiconductor wafers (e.g., two 12″ diameter semiconductor wafers). In other embodiments, the W2W bonding process may involve a bonding of different size semiconductor wafers. As a result of the W2W bonding process, at least one semiconductor structure in the set of semiconductor structures 432 may be electrically coupled to the at least one active device in the set of semiconductor mesas 412.

As shown in FIG. 4G, the carrier wafer 406 may be removed after the W2W bonding process illustrated in FIG. 4F is performed. Optionally, a dielectric optical element 436 (or other optical element, including an MOE) may be attached to the light emission surface of the set of semiconductor mesas 412. In some embodiments, the dielectric optical element 436 may be bonded to the first dielectric 408 using a D2W bonding process. In some embodiments, one or more coatings or surface treatments 440 may be deposited on or applied to the dielectric optical element 436, to reflect a portion of light emitted by an active device (e.g., a laser diode) back toward the laser diode and function as an extent of an extended laser cavity. The extended laser cavity, in combination with a VCSEL as an active element in the set of semiconductor mesas 412, may form a VECSEL. Also shown in FIG. 4G is the formation (e.g., etching) of one or more wells 438 through one or more dielectrics, to expose the electrical contacts (e.g., conductive pads) 434.

Following the steps shown in FIG. 4G, the electronic device shown in FIG. 4G may be diced from other devices that were formed in parallel on a same set of semiconductor wafers.

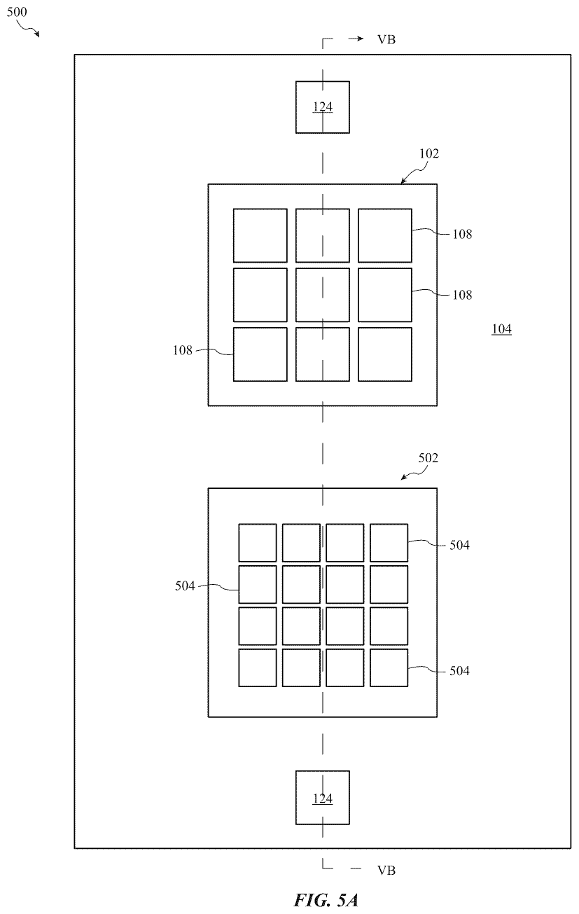

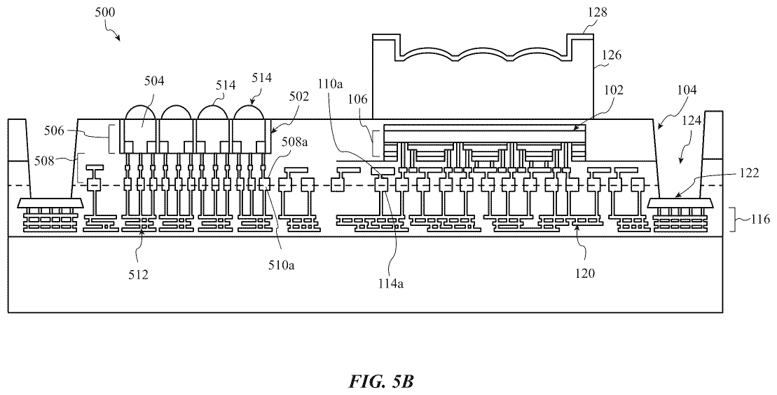

FIGS. 5A and 5B show an example electronic device 500 having a first die 102 and a second die 502 embedded in one or more dielectrics 104 on a silicon backplane or interposer. FIG. 5A shows a plan view of the electronic device 500. FIG. 5B shows a cross-sectional elevation of the electronic device 500, taken along line VB-VB in FIG. 1A. By way of example, the electronic device 500 includes many of the structures and features of the electronic device described with reference to FIGS. 1A and 1B, and like reference numerals are used to refer to like structures and features. However, in the electronic device 500, the first set of hybrid bonding pads 110a of the first die 102 may be bonded to the second set of hybrid bonding pads 114a using a D2W bonding technique.

In addition to the structures and features shared with the electronic device described with reference to FIGS. 1A and 1B, the electronic device 500 includes a die 502. By way of example, the die 502 is shown to be a die including one or more (e.g., an array of) single-photon avalanche diodes (SPADs) 504. The die 502 may additionally, or alternatively, include other types of semiconductor devices. The SPAD(s) 504 may be formed in a third set of semiconductor layers 506.

The die 502 may include a third set of conductors 508 that route electrical signals to and/or from the SPAD(s) 504. The third set of conductors 508 may include a third set of hybrid bonding pads 508a on a surface of the die 502.

The fourth dielectric 112 may include a fourth set of conductors 510, routed in or on the fourth dielectric 112. The fourth set of conductors 510 may include a fourth set of hybrid bonding pads 510a. The fourth set of hybrid bonding pads 510a may be bonded to the third set of hybrid bonding pads 508a at a D2W bonding interface.

In some embodiments, a second set of semiconductor structures 512 (e.g., transistors or other components) may be formed (or included) in the set of semiconductor and metal layers 116. Conductors 510b (e.g., conductive vias and/or conductive traces) in the fourth set of conductors 510 may electrically couple semiconductor structures in the second set of semiconductor structures 512 to the fourth set of hybrid bonding pads 510a. By means of bonding the fourth set of hybrid bonding pads 510a to the third set of hybrid bonding pads 508a, at least one semiconductor structure in the second set of semiconductor structures 512 may be electrically coupled to the SPAD(s) 504.

In some embodiments, conductors in the fourth set of conductors 510 may electrically couple semiconductor structures in the second set of semiconductor structures 512 and/or conductors in the third set of conductors 510 to one or more surface electrical contacts (e.g., conductive pads) 122 disposed in one or more wells 124 etched through the set of dielectrics 104 and some or all of the semiconductor layers in the set of semiconductor and metal layers 116.

Optionally, one or more dielectric optical elements 514 may be attached to the second die 502. The dielectric optical element(s) 514 may define at least one lens positioned to direct light toward the at least one SPAD 504. In some embodiments, the dielectric optical element(s) 514 may include a glass, a plastic, or a crystal (e.g., a sapphire). In some embodiments, one or more anti-reflective coatings or surface treatments may be deposited on or applied to the dielectric optical element(s) 514.

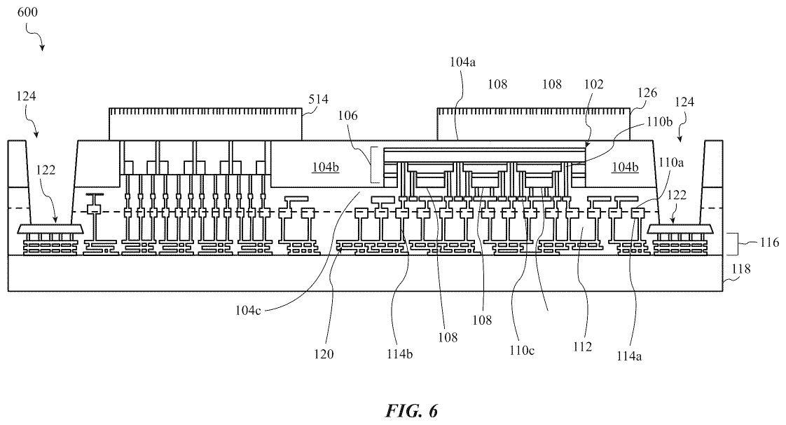

FIG. 6 shows a variation 600 of the electronic device described with reference to FIGS. 5A and 5B. In the variation 600, the dielectric optical element 126 is an MOE instead of (or in addition to) one or more lenses. The dielectric optical element 514 may also be an MOE. Alternatively, one of the dielectric optical elements 126, 514 may be an MOE and the other dielectric optical element may be a lens or other type of dielectric optical element.

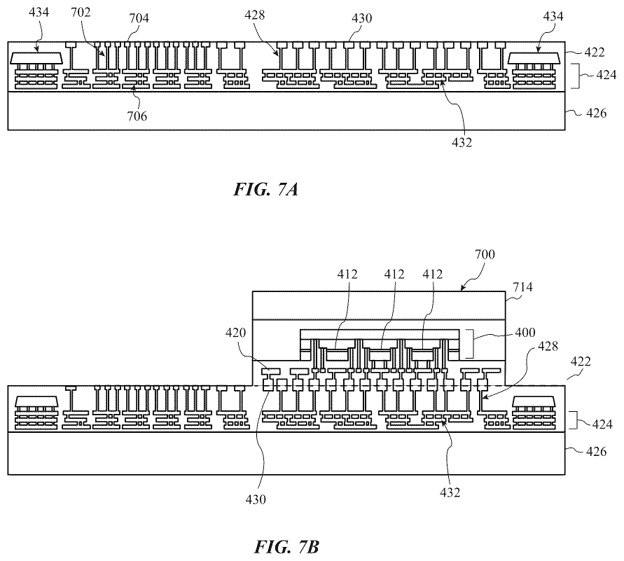

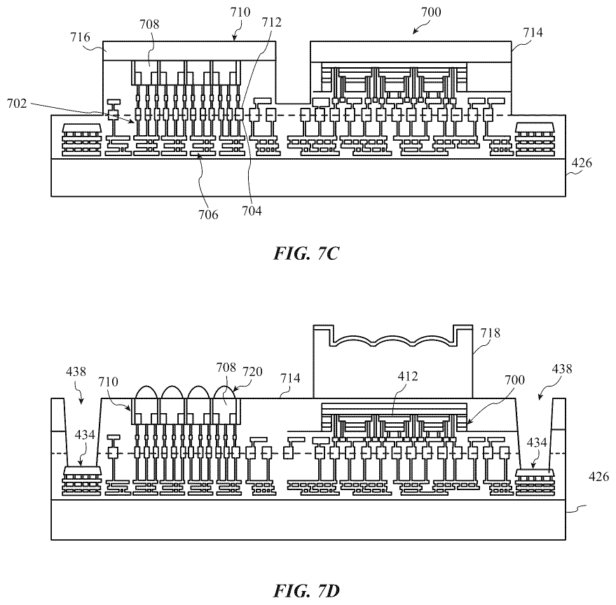

FIGS. 7A-7D, in combination with FIGS. 4A-4D, illustrate an example method of making the electronic device shown in any of FIGS. 5A and 5B, or 6.

The method may include performing the operations described with reference to FIGS. 4A-4D, before, after, or in parallel with the operations described with reference to FIG. 7A. At the completion of the operations described with reference to FIG. 4D, however, a first die 700 including the set of semiconductor mesas 412 may be diced from the carrier wafer 406 and first set of semiconductor layers 400.

As shown in FIG. 7A, a fourth dielectric 422 (e.g., SiO₂ or SiN) and optional set of semiconductor and metal layers 424 may be formed on a semiconductor substrate 426 (e.g., another Si wafer). A second set of conductors 428 may be routed in or on the fourth dielectric 422 and include a second set of hybrid bonding pads 430. A third set of conductors 702 may also be routed in or on the fourth dielectric 422 and include a third set of hybrid bonding pads 704.

The set of semiconductor and metal layers 424 may be disposed between the semiconductor substrate 426 and the second and third sets of hybrid bonding pads 430, 704. In some embodiments, the set of semiconductor and metal layers 424 may include a first set of semiconductor structures 432 and a second set of semiconductor structures 706 (e.g., transistors or other components). The first set of semiconductor structures 432 may define, for example, one or more LDD circuits that may be electrically coupled to the at least one active device (in the set of semiconductor mesas 412) via the first set of conductors (e.g., the conductive vias 416, the conductive traces, and the first set of hybrid bonding pads 420) and the second set of conductors 428. If the at least one active device includes a photodetector (e.g., an RCPD), the set of semiconductor structures 432 may also define a sense circuit or readout circuit. The second set of semiconductor structures 706 may define, for example, one or more SPAD logic circuits that may be electrically coupled to at least one SPAD 708 in a second die 710 via the third set of conductors 702 and a fourth set of conductors in the second die 710.

Conductors (e.g., conductive vias and/or conductive traces) in the second set of conductors 428 may electrically couple semiconductor structures in the first set of semiconductor structures 432 to the second set of hybrid bonding pads 430. Conductors (e.g., conductive vias and/or conductive traces) in the third set of conductors 702 may electrically couple semiconductor structures in the second set of semiconductor structures 706 to the third set of hybrid bonding pads 704.

In some embodiments, conductors in the second and third sets of conductors 428, 702 may electrically couple semiconductor structures in the first and second sets of semiconductor structures 432, 706 and/or conductors in the first or fourth sets of conductors to one or more electrical contacts 434 (e.g., conductive pads).

As shown in FIG. 7B, the second set of hybrid bonding pads 430 may be bonded to the first set of hybrid bonding pads 420 of the first die 700 in a D2W bonding process. The D2W bonding process may be any currently known or otherwise discovered D2W bonding process. As a result of the D2W bonding process, at least one semiconductor structure in the first set of semiconductor structures 432 may be electrically coupled to the at least one active device in the set of semiconductor mesas 412.

As shown in FIG. 7C, the third set of hybrid bonding pads 704 may be bonded to a fourth set of hybrid bonding pads 712 of the second die 710 in a D2W bonding process. The D2W bonding process may be any currently known or otherwise discovered D2W bonding process. As a result of the D2W bonding process, at least one semiconductor structure in the second set of semiconductor structures 706 may be electrically coupled to at least one SPAD 708 in the second die 710.

As shown in FIG. 7D, a dielectric 714 (e.g., SiO2 or SiN) may be formed or deposited between and around (i.e., abutting) the perimeters of the first and second die 700, 710. Subsequently (or prior to) the formation or deposition of the dielectric 714, the carrier wafer 406 may be removed from the first die 700, and a carrier wafer 716 may be removed from the second die 710, after the D2W bonding processes illustrated in FIG. 7C are performed.

As also shown in FIG. 7D, a dielectric optical element 718 (or other optical element(s), including an MOE) may be attached to the light emission surface of the set of semiconductor mesas 412. In some embodiments, the dielectric optical element 718 may be bonded to the first die 700 using a D2W bonding process. As further shown in FIG. 7D, one or more dielectric optical elements 720 (e.g., one or more lenses; or another type of optical element or elements, including an MOE) may be attached to the light receiving surface of the at least one SPAD 708. In some embodiments, the dielectric optical element(s) 720 may be bonded to the second die 710 using a D2W bonding process.

FIG. 7D also shows the formation (e.g., etching) of one or more wells 438 through one or more dielectrics, to expose the electrical contacts (e.g., conductive pads) 434.

Following the steps shown in FIG. 7D, the electronic device shown in FIG. 7D may be diced from other devices that were formed in parallel on the semiconductor substrate (e.g., semiconductor wafer) 426.

The foregoing description, for purposes of explanation, uses specific nomenclature to provide a thorough understanding of the described embodiments. However, it will be apparent to one skilled in the art, after reading this description, that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art, after reading this description, that many modifications and variations are possible in view of the above teachings.

What is claimed is:

1. An electronic device, comprising:
a set of semiconductor layers defining a set of semiconductor mesas;
a first dielectric abutting the set of semiconductor layers at a perimeter of the set of semiconductor layers;
a second dielectric on the set of semiconductor mesas; and
a set of conductors routed in or on the second dielectric, the set of conductors electrically connected to at least one active device defined in at least one semiconductor mesa of the set of semiconductor mesas, the set of conductors configured to route electrical signals to or from the at least one semiconductor mesa, and the set of conductors including a set of hybrid bonding pads on the second dielectric.

2. The electronic device of claim 1, wherein:
the set of semiconductor layers is a first set of semiconductor layers;
the set of hybrid bonding pads is a first set of hybrid bonding pads; and
the electronic device further comprises:
a third dielectric on the second dielectric; and
a second set of conductors routed in or on the third dielectric, the second set of conductors including a second set of hybrid bonding pads bonded to the first set of hybrid bonding pads;
a semiconductor substrate; and
a set of semiconductor structures formed in a second set of semiconductor layers on the semiconductor substrate, the second set of semiconductor layers disposed between the semiconductor substrate and the second set of hybrid bonding pads.

3. The electronic device of claim 2, wherein the first set of semiconductor layers comprise a different set of semiconductor materials than the second set of semiconductor layers.

4. The electronic device of claim 2, wherein:
the first set of semiconductor layers is included in a die diced from a first semiconductor wafer having a first diameter; and
the semiconductor substrate and the second set of semiconductor layers is diced from a second semiconductor wafer having a second diameter, the second diameter different from the first diameter.

5. The electronic device of claim 1, wherein the at least one active device comprises at least one surface-emitting laser diode.

6. The electronic device of claim 1, wherein the at least one active device comprises at least one resonant cavity photodetector (RCPD).

7. The electronic device of claim 1, wherein the set of conductors comprises a set of conductive vias electrically coupled to the at least one active device.

8. The electronic device of claim 1, wherein:
the set of semiconductor layers is included in a die diced from a semiconductor wafer having a first diameter; and
the set of semiconductor mesas has a pitch that differs from an achievable pitch of a processing toolset for the semiconductor wafer having the first diameter.

9. An electronic device, comprising:
a first set of semiconductor layers defining a set of semiconductor mesas;
a dielectric on the set of semiconductor mesas; and
a set of conductors routed in the dielectric, the set of conductors including a set of conductive vias electrically connected to at least one active device defined in at least one semiconductor mesa of the set of semiconductor mesas, the set of conductors configured to route electrical signals to or from the at least one semiconductor mesa.

10. The electronic device of claim 9, further comprising a dielectric optical element attached to the first set of semiconductor layers, on a side of the set of semiconductor mesas opposite a side of the set of semiconductor mesas including the dielectric, the dielectric optical element defining at least one lens positioned to direct light to or from the at least one active device.

11. The electronic device of claim 10, wherein:
the dielectric is a first dielectric; and
the electronic device further includes a second dielectric disposed between the set of semiconductor mesas and the dielectric optical element.

12. The electronic device of claim 9, further comprising a multivariate optical element attached to the first set of semiconductor layers, on a side of the set of semiconductor mesas opposite a side of the set of semiconductor mesas including the dielectric.

13. An electronic device, comprising:
a set of semiconductor layers defining a set of semiconductor mesas;
a first dielectric on the set of semiconductor mesas;
a first set of conductors routed in or on the first dielectric, the first set of conductors electrically connected to at least one active device defined in at least one semiconductor mesa of the set of semiconductor mesas, the first set of conductors configured to route electrical signals to or from the at least one semiconductor mesa, and the first set of conductors including a first set of hybrid bonding pads on the first dielectric;
a second dielectric on the first dielectric; and
a second set of conductors routed in or on the second dielectric, the second set of conductors including a second set of hybrid bonding pads bonded to the first set of hybrid bonding pads.

14. The electronic device of claim 13, wherein:
the set of semiconductor layers is a first set of semiconductor layers; and
the electronic device further comprises:
a semiconductor substrate; and
a set of semiconductor structures formed in a second set of semiconductor layers on the semiconductor substrate, the second set of semiconductor layers disposed between the semiconductor substrate and the second set of hybrid bonding pads.

15. The electronic device of claim 14, wherein the set of semiconductor structures define at least one laser diode driver (LDD) circuit, the at least one LDD circuit electrically coupled to the at least one active device via the first set of conductors and the second set of conductors.

16. The electronic device of claim 13, wherein:
the set of semiconductor layers is included in a first die; and
the electronic device further comprises:
a second die;
a third dielectric on the second die;
a third set of conductors routed in or on the third dielectric, the third set of conductors electrically connected to at least one device in the second die and configured to route electrical signals to or from the at least one device, and the third set of conductors including a third set of hybrid bonding pads on the third dielectric; and
a fourth set of conductors routed in or on the second dielectric, the fourth set of conductors including a fourth set of hybrid bonding pads bonded to the third set of hybrid bonding pads.

17. The electronic device of claim 16, further comprising a fourth dielectric abutting a first perimeter of the first die and a second perimeter of the second die.

18. The electronic device of claim 16, wherein the second die comprises at least one single-photon avalanche detector (SPAD).

19. The electronic device of claim 18, wherein:
the set of semiconductor layers is a first set of semiconductor layers; and
the electronic device further comprises:
a semiconductor substrate; and
a first set of semiconductor structures and a second set of semiconductor structures formed in a second set of semiconductor layers on the semiconductor substrate, the second set of semiconductor layers disposed between the semiconductor substrate and the second and fourth sets of hybrid bonding pads, the first set of semiconductor structures defining at least one laser diode driver (LDD) circuit, and the second set of semiconductor structures defining at least one SPAD logic circuit.

20. The electronic device of claim 13, wherein the at least one active device comprises a surface-emitting laser diode.
